(19) United States
(12) Patent Application Publication
(10) Pub. No.: US 2009/0032229 A1
(43) Pub. Date: Feb. 5, 2009

(54) METHODS AND SYSTEMS FOR COOLING INVERTERS FOR VEHICLES

(75) Inventors: Gabriel GALLEGOS-LOPEZ, Torrance, CA (US); Khiet LE, Mission Viejo, CA (US); David F. NELSON, Agoura Hills, CA (US); George JOHN, Cerritos, CA (US); Gregory S. SMITH, Woodland Hills, CA (US); Gregory D. ROSDAHL, Dominguez Hills, CA (US)

Correspondence Address: INGRASSIA FISHER & LORENZ, P.C. (GM), 7010 E. COCHISE ROAD, SCOTTSDALE, AZ, 85253, US

(73) Assignee: GM GLOBAL TECHNOLOGY OPERATIONS, INC., DETROIT, MI (US)

(21) Appl. No.: 12/171,851

(22) Filed: Jul. 11, 2008

Related U.S. Application Data
(60) Provisional application No. 60/952,735, filed on Jul. 30, 2007.

(51) Int. Cl. F28D 15/00; G05D 16/00; B60H 1/32; G05D 7/00; H05K 7/20

(52) U.S. Cl. 165/104.33; 165/286; 165/41; 700/282; 363/141

(57) ABSTRACT

A method for cooling an inverter of a vehicle system includes the steps of providing a flow of cooling fluid to the inverter, determining a value of a variable that is influenced at least in part by the flow of cooling fluid to the inverter, and regulating the flow of cooling fluid to the inverter based at least in part on the value of the variable.

### CROSS-REFERENCES TO RELATED APPLICATIONS

This application claims the benefit of U.S. Provisional Application No. 60/952,735, filed Jul. 30, 2007 (the entire content of which is incorporated herein by reference).

### TECHNICAL FIELD

The present invention generally relates to the field of vehicles and, more specifically, to methods and systems for cooling inverters for vehicles.

### BACKGROUND OF THE INVENTION

Many vehicles today have high-powered inverters that invert electrical current between a direct current power source and a motor of the vehicle that uses alternating current. For example, in a traditional electric vehicle, a high-powered inverter is typically coupled between a direct current battery pack and an electric current machine that uses alternating current to drive a motor of the vehicle. As another example, in a fuel cell vehicle, a high-powered inverter is typically coupled between a direct current fuel cell and an electric current machine that uses alternating current.

High-powered inverters generally require cooling to ensure optimal performance and to prevent over-heating. In many vehicles, high-powered inverters are liquid cooled to remove heat from inverter. Spray cooling is a technique where fluid is sprayed either directly or indirectly against components inside the high-power inverter. However, it is often difficult to provide optimal cooling for a high-powered inverter, for example because it is often difficult to maintain a constant flow of cooling fluid toward the high-power inverter, when liquid changes phase.

Accordingly, it is desired to provide an improved method for cooling an inverter, for example that provides for an optimal flow of cooling fluid to the inverter. It is also desired to provide an improved program product for cooling an inverter, for example that provides for an optimal flow of cooling fluid to the inverter. It is further desired to provide an improved system for cooling an inverter, for example that provides for an optimal flow of cooling fluid to the inverter

Furthermore, other desirable features and characteristics of the present invention will be apparent from the subsequent detailed description and the appended claims, taken in conjunction with the accompanying drawings and the foregoing technical field and background.

### SUMMARY OF THE INVENTION

In accordance with an exemplary embodiment of the present invention, a method for cooling an inverter of a vehicle system is provided. The method comprises the steps of providing a flow of cooling fluid to the inverter, determining a value of a variable that is influenced at least in part by the flow of cooling fluid to the inverter, and regulating the flow of cooling fluid to the inverter based at least in part on the value of the variable.

In accordance with another exemplary embodiment of the present invention, a program product for calculating a control gain for use in controlling cooling flow rate in inverter is provided. The program product comprises a program and a computer-readable signal-bearing media. The program is configured to at least facilitate providing a flow of cooling fluid to the inverter, determining a value of a variable that is influenced at least in part by the flow of cooling fluid to the inverter, and regulating the flow of cooling fluid to the inverter based at least in part on the value of the variable. The computer-readable signal-bearing media bears the program.

In accordance with a further exemplary embodiment of the present invention, a cooling system for cooling an inverter of a vehicle system is provided. The cooling system comprises a pump, a sensing device, and a control unit. The pump is configured to at least facilitate providing a flow of cooling fluid to the inverter. The sensing device is configured to at least facilitate determining a value of a variable that is influenced at least in part by the flow of cooling fluid to the inverter. The control unit is coupled to the sensing device and the pump, and is configured to at least facilitate regulating the flow of cooling fluid to the inverter based at least in part on the value of the variable.

### BRIEF DESCRIPTION OF THE DRAWINGS

The present invention will hereinafter be described in conjunction with the following drawing figures, wherein like numerals denote like elements, and wherein:

FIG. 1 is a functional block diagram showing a cooling system for cooling an inverter of a vehicle, in accordance with an exemplary embodiment of the present invention;

FIG. 2 is a flowchart of a process for cooling an inverter of a vehicle, that can be implemented in connection with the cooling system of FIG. 1, in accordance with an exemplary embodiment of the present invention;

FIG. 3 is a flowchart of one implementation of a step of the process of FIG. 2, namely a step of determining a value of a variable that is influenced by a flow of cooling fluid to the inverter, in accordance with an exemplary embodiment of the present invention;

FIG. 4 is a flowchart of another implementation of the step of determining a value of a variable that is influenced by a flow of cooling fluid to the inverter in the process of FIG. 2, in accordance with an exemplary embodiment of the present invention;

FIG. 5 is a flowchart of one implementation of another step of the process of FIG. 2, namely a step of adjusting a flow of cooling fluid to the inverter based on the value of the variable that is influenced by the flow of cooling fluid to the inverter, in accordance with an exemplary embodiment of the present invention;

FIG. 6 is a functional block diagram of a computer system that can be implemented in connection with the cooling system of FIG. 1 and the process of FIG. 2, in accordance with an exemplary embodiment of the present invention;

FIG. 7 is a plot showing an effect of the cooling system of FIG. 1 and the process of FIG. 2 on a pressure difference chamber versus nozzle in an inverter of a vehicle, in accordance with an exemplary embodiment of the present invention; and

FIG. 8 is a plot showing an effect of the cooling system of FIG. 1 and the process of FIG. 2 on a rate of flow of cooling fluid toward an inverter of a vehicle, in accordance with an exemplary embodiment of the present invention.

### DETAILED DESCRIPTION OF THE INVENTION

The following detailed description is merely exemplary in nature, and is not intended to limit the invention or the application and uses of the invention. Furthermore, there is no intention to be bound by any expressed or implied theory presented in the preceding technical field, background, brief summary or the following detailed description.

Embodiments of the invention may be described herein in terms of functional and/or logical block components and various processing steps. It should be appreciated that such block components may be realized by any number of hardware, software, and/or firmware components configured to perform the specified functions. For example, an embodiment of the invention may employ various integrated circuit components, e.g., memory elements, digital signal processing elements, logic elements, look-up tables, or the like, which may carry out a variety of functions under the control of one or more microprocessors or other control devices. In addition, those skilled in the art will appreciate that embodiments of the present invention may be practiced in conjunction with any number of different inverters for any number of different types of vehicles.

For the sake of brevity, conventional techniques related to signal processing, data transmission, signaling, control, and other functional aspects of the systems (and the individual operating components of the systems) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment of the invention.

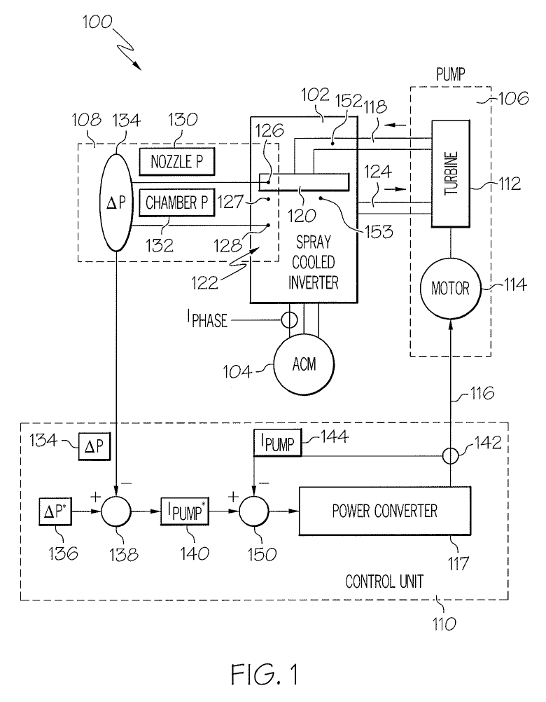

FIG. 1 is a functional block diagram showing a cooling system 100 for cooling an inverter 102 of a vehicle, in accordance with an exemplary embodiment of the present invention. In a preferred embodiment, the inverter 102 is a high-power inverter coupled between a non-depicted direct current source (such as a battery pack, a fuel cell, or any one of a number of other different types of direct current sources) to an alternating current machine 104. The alternating current machine 104 preferably operates one or more non-depicted devices and/or systems of the vehicle, such as a transmission of the vehicle, a motor of the vehicle, and/or any one or more of a number of other different types of devices and/or systems.

As depicted in FIG. 1, the inverter 102 includes a pump 106, a sensing unit 108, and a control unit 110. In the depicted embodiment, the pump 106 includes a turbine 112 and a motor 114. The motor 114 receives an electric current 116, preferably from a power converter 117 of the control unit 110, and uses the electric current to 116 to operate the turbine 112. The turbine 112 provides cooling fluid via a first channel 118 to a nozzle 120, where the cooling fluid is then sprayed against components of the inverter 102 inside a chamber 122 of the inverter 102. The turbine 112 also receives the cooling fluid as it returns from the inverter 102 via a second channel 124. In one preferred embodiment the first and second channels 118, 124 comprise hoses; however, this may vary in other embodiments.

The sensing unit 108 comprises one or more sensors configured to determine a value of one or more variables that are influenced at least in part by the flow of cooling fluid to the inverter. In a preferred embodiment, the sensing unit 108 determines a pressure difference 134 between the nozzle 120 and the chamber 122. In other embodiments, the sensing unit 108 may determine values of one or more other variables, such as a change in the electric current 116, a direct measure of the flow of cooling fluid to the inverter 102, a phase current of the inverter 102, and/or one or more other variables. The sensing unit 108 preferably provides values of the pressure difference 134 and/or other variables to the control unit 110 for regulation and control by the control unit 110.

In one version of the depicted embodiment, the sensing unit 108 comprises a first pressure sensor 126 and a second pressure sensor 128. The first pressure sensor 126 is configured to determine a first pressure 130 outside the chamber 122. As depicted, the first pressure sensor 126 is disposed within the nozzle 120. However, this may vary in other embodiments, for example in that the first pressure sensor 126 may be disposed inside the first channel 118 in other embodiments. The second pressure sensor 128 is configured to determine a second pressure 132 inside the chamber 122. The second pressure sensor 128 is preferably disposed inside the chamber 122.

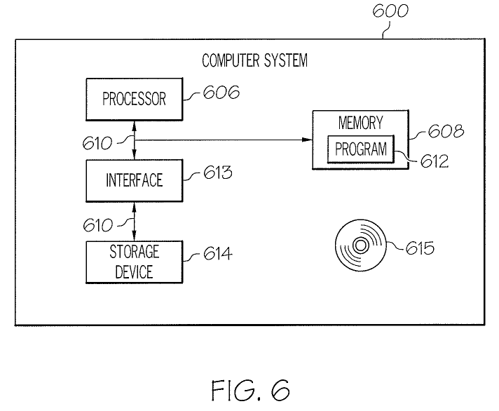

In this version of the depicted embodiment, the sensing unit 108 determines a pressure difference 134 by subtracting the second pressure 132 from the first pressure 130, or vice versa. In other embodiments, this subtraction may be conducted in whole or in part by the control unit 110 thereof, for example by a processor thereof, such as the processor depicted in FIG. 6 and described further below in connection therewith.

In another version of the depicted embodiment, the sensing unit 108 includes a flow meter 127. The flow meter 127 provides a direct measure of the pressure difference 134 between the nozzle 120 and the chamber 122. The flow meter 127 is preferably coupled between the nozzle 120 and the chamber 122.

In both of these two exemplary embodiments, the value of the pressure difference 134 is provided to the control unit 110 for regulation. The value of the pressure difference 134 serves as a representation of a change in rate of flow of the cooling fluid from the turbine 112 to the inverter 102. Specifically, the pressure difference 134 is at least approximately proportional to the change in rate of flow of the cooling fluid from the turbine 112 to the inverter 102. As such, by regulating the pressure difference 134, the control unit 110 thereby also regulates the rate of the cooling fluid from the turbine 112 to the inverter 102.

The control unit 110 is coupled between the sensing unit 108 and the pump 106. The control unit 110 includes the above-referenced power converter 117 that supplies the electric current 116 to the motor 114, as well as a current sensor 142 that measures the amount of the electric current 116 provided to the motor 114. Also in a preferred embodiment, the control unit 110 comprises and/or utilizes a non-depicted computer system having an interface, a memory, and a processor, such as the computer system set forth in FIG. 6 and described further below in connection therewith.

The control unit 110 is configured to obtain the value of the above-referenced variable from the sensing unit 108, and to regulate the flow of cooling fluid from the pump 106 to the inverter 102 based at least in part on the value of the variable. In a preferred embodiment, the control unit 110 receives the value of the pressure difference 134 from the sensing unit 108. The control unit 110 regulates the electric current 116 provided to the motor 114, thereby regulating the flow of cooling fluid to the inverter 102, based upon the value of the pressure difference 134, as discussed in greater detail below.

Specifically, in a preferred embodiment, the control unit 110 compares the value of the variable. In a preferred embodiment, the desired electric current value 140 is determined based upon the pressure difference 134 to a desired pressure difference 136, thereby generating a desired pressure comparison 138. The desired pressure difference 136 preferably represents an optimal difference between the first and second pressures 130, 132 that corresponds with an optimal flow of cooling fluid from the turbine 112 to the inverter 102. In one preferred embodiment, the desired pressure difference 136 represents an optimal difference between the first and second pressures 130, 132 that corresponds with an approximately constant flow of cooling fluid from the turbine 112 to the inverter 102. In one preferred embodiment, the desired pressure difference 136 is stored in a memory of the control unit 110, such as the memory depicted in FIG. 6 and described further below in connection therewith. However, this may vary in other embodiments. Also in one preferred embodiment, the desired pressure comparison 138 is generated by a processor of the control unit 110, such as the processor depicted in FIG. 6 and described further below in connection therewith. However, this may also vary in other embodiments.

The control unit 110 also determines a desired electric current value 140 based upon the desired pressure comparison 138. Preferably, the control unit 110 determines the desired electric current value 140 by calculating the amount of the electric current 116 that would be needed to be provided to the motor 114 to result in the pressure difference 134 being made equal to the desired pressure difference 136. The amount of the electric current 116 that would be needed to equalize the pressure difference 134 and the desired pressure difference 136 is considered to be the desired electric current value 140 in the depicted embodiment. In one preferred embodiment, the desired electric current value 140 is determined by a processor of the control unit 110, such as the processor depicted in FIG. 6 and described further below in connection therewith. However, this may also vary in other embodiments.

In the depicted embodiment, the control unit 110 also includes the above-referenced current sensor 142 coupled to the power converter 117. The current sensor 142 measures an electric current value 144 representing an amount of the electric current 116 being provided by the power converter 117 to the motor 114. The control unit 110 compares the electric current value 144 to the desired electric current value 140, thereby generating a desired electric current comparison 150. In one preferred embodiment, the desired electric current comparison 150 is generated by a processor of the control unit 110, such as the processor depicted in FIG. 6 and described further below in connection therewith. However, this may also vary in other embodiments.

The desired electric current comparison 150 is provided to the power converter 117, which then adjusts the amount of the electric current 116 provided to the motor 114 accordingly. Specifically, if the desired electric current comparison 150 indicates that the electric current value 144 is less than the desired electric current value 140, then the power converter 117 increases the amount of the electric current 116 provided to the motor 114 until the electric current value 144 and the desired electric current value 140 are equalized. Conversely, if the desired electric current comparison 150 indicates that the electric current value 144 is greater than the desired electric current value 140, then the power converter 117 decreases the amount of the electric current 116 provided to the motor 114 until the electric current value 144 and the desired electric current value 140 are equalized.

In a preferred embodiment, such changes in the electric current 116 provided to the motor 114 are implemented by the power converter 117 based upon electric current commands received by the power converter 117 from a processor of the control unit 110, such as the processor depicted in FIG. 6 and described further below in connection therewith. Preferably, the processor generates the electric current commands based upon the desired electric current comparison 150 and transmits the electric commands to the power converter 117 for implementation.

In other embodiments, the cooling system 100 may control the flow of cooling fluid to the inverter 102 via values of one or more variables other than the pressure difference 134 as described above. For example, in one alternate embodiment, the variable comprises a direct measure of the flow of cooling fluid to the inverter 102 over time, as measured by one or more flow sensors 152 that may be coupled to the first channel 118 (as depicted in FIG. 1), or alternatively coupled to the turbine 112, the nozzle 120, the chamber 122, and/or the second channel 124. In such an embodiment, the electric current 116 provided by the power converter 117 to the motor 114 can be similarly adjusted so that the flow of cooling fluid to the inverter 102 is maintained at a desired value. In another alternate embodiment, the variable comprises a phase current of the inverter 102, as measured by one or more phase current sensors 153 that may be disposed within or coupled to the inverter 102 (as depicted in FIG. 1). In such an embodiment, the electric current 116 provided by the power converter 117 to the motor 114 can be similarly adjusted, and the flow of cooling fluid to the inverter 102 thereby regulated, so that the phase current of the inverter 102 is maintained at a desired value. Various other variables and techniques may also be used in other embodiments.

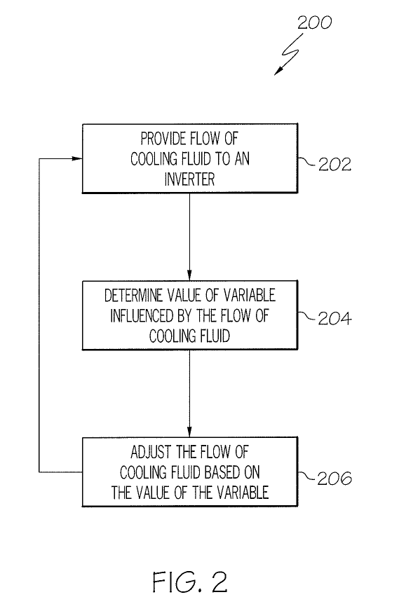

FIG. 2 is a flowchart of a process 200 for cooling an inverter of a vehicle, in accordance with an exemplary embodiment of the present invention. The process 200 can be implemented by and/or utilized in connection with the cooling system 100 of FIG. 1.

As depicted in FIG. 2, the process 200 begins with the step of providing a flow of cooling fluid to an inverter of a vehicle (step 202). In one preferred embodiment, the flow of cooling fluid is provided to the inverter 102 of FIG. 1 via the turbine 112 of the pump 106 of FIG. 1.

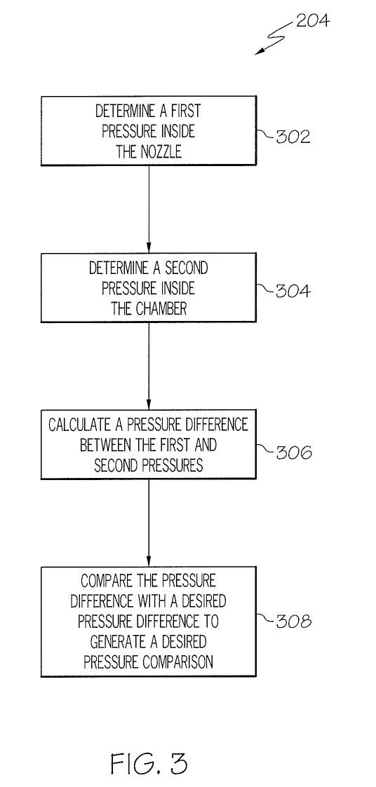

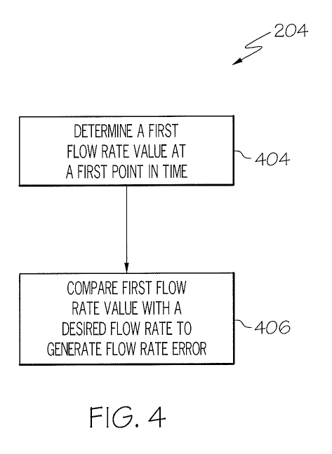

Next, a value of a variable is determined (step 204). The variable can be any one of a number of different variables that are influenced at least in part by the flow of cooling fluid to the inverter. Preferably the value of the variable is determined by or using the sensing unit 108 of FIG. 1. Certain exemplary embodiments of step 204 are depicted in FIGS. 3 and 4, corresponding to different exemplary variables, and will be described further below in connection with these Figures.

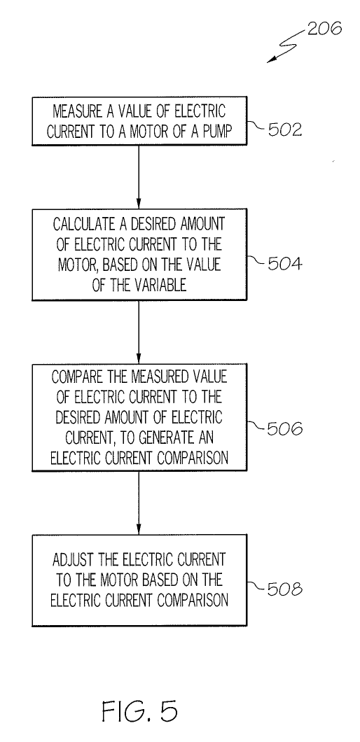

The flow of cooling fluid to the inverter is then adjusted, based upon the value of the variable (step 206). The flow of cooling fluid is preferably adjusted by the control unit 110 of FIG. 1. In addition, the flow of cooling fluid to the inverter is preferably adjusted so that the flow of cooling fluid to the inverter remains approximately constant. An exemplary embodiment of step 206 is depicted in FIG. 5, and will be described further below in connection therewith.

FIG. 3 is a flowchart of one exemplary embodiment of step 204 of the process 200 of FIG. 2, namely the step of determining the value of a variable that is influenced at least in part by the flow of cooling fluid to the inverter. In the embodiment of FIG. 3, the variable comprises a comparison between a desired difference and an actual difference in pressure inside a chamber of the inverter versus a pressure in the nozzle.

In one such embodiment, a first pressure is first obtained inside the nozzle (step 302). In one preferred embodiment, the first pressure corresponds to the first pressure 130 of FIG. 1, and is determined by the first pressure sensor 126 of FIG. 1. In addition, a second pressure is obtained inside the chamber of the inverter (step 304). In one preferred embodiment, the second pressure corresponds to the second pressure 132 of FIG. 1, and is determined by the second pressure sensor 128 of FIG. 1. It will be appreciated that the first and second pressures may be determined simultaneously or in either order, regardless of the order depicted in FIG. 3 or described herein in connection therewith.

A pressure difference is then calculated (step 306). Specifically, the pressure difference is calculated by subtracting the second pressure from the first pressure, or vice versa. In one preferred embodiment, the pressure difference corresponds to the pressure difference 134 of FIG. 1. Also in one preferred embodiment, the pressure difference is calculated by the sensing unit 108 of FIG. 1. In an alternate preferred embodiment, the pressure difference is calculated by the control unit 110 of FIG. 1. In another exemplary embodiment, the pressure difference may be determined directly by a flow meter, such as the flow meter 127 of FIG. 1.

The pressure difference is then compared with a desired pressure difference, to thereby generate a desired pressure comparison (step 308). In one preferred embodiment, the desired pressure difference corresponds to the desired pressure difference 136 of FIG. 1, and the desired pressure comparison corresponds to the desired pressure comparison 138 of FIG. 1 and is generated by the control unit 110 of FIG. 1, for example by a non-depicted processor thereof. The desired pressure comparison can then be used as the value of the variable used in adjusting the flow of cooling fluid to the inverter in step 206 of the process 200 of FIG. 2.

Turning now to FIG. 4, a flowchart is provided for another exemplary embodiment of step 204 of the process 200 of FIG. 2, namely the step of determining the value of a variable that is influenced at least in part by the flow of cooling fluid to the inverter. In the embodiment of FIG. 4, the variable comprises a direct measure of the flow of cooling fluid to the inverter.

A first flow value is determined for a rate of flow of cooling fluid to the inverter at a first point in time (step 404). Next, compare first flow rate value with a desired flow rate to generate flow rate error (step 406). In one preferred embodiment, the first flow value is determined by the flow sensor 152 of FIG. 1, which may be coupled to the pump 106, the first channel 118, the nozzle 120, the chamber 122, and/or the second channel 124 of FIG. 1.

The flow rate error can then be used as the value of the variable used in adjusting the flow of cooling fluid to the inverter in step 206 of the process 200 of FIG. 2.

FIG. 5 is a flowchart of one exemplary embodiment of step 206 of the process 200 of FIG. 2, namely the step of adjusting the flow of cooling fluid to the inverter based on the value of the variable. In this embodiment, an electric current value is measured, representing an amount of electric current that is being provided to a motor (step 502). In one preferred embodiment, the electric current value corresponds to the electric current value 144 of FIG. 1, and is determined by the current sensor 142 of FIG. 1.

In addition, a desired amount of electric current for providing to the motor is calculated (step 504). In one preferred embodiment, the desired amount of electric current corresponds to the desired electric current value 140 of FIG. 1. It will be appreciated that the electric current value and the desired amount of electric current may be measured/calculated simultaneously or in either order, regardless of the order depicted in FIG. 5 or described herein in connection therewith.

The electric current value and the desired amount of electric current are then compared with one another, to thereby generate an electric current comparison (step 506). In one preferred embodiment, the electric current comparison corresponds to the desired electric current comparison 150 of FIG. 1. In one preferred embodiment, the electric current comparison is generated by a processor of the control unit 110 of FIG. 1.

The amount of electric current provided to the motor is then adjusted, based on the electric current comparison. In one preferred embodiment, the electric current is adjusted by the control unit 110 of FIG. 1 so that the electric current comparison approaches zero. Specifically, the electric current is preferably adjusted by a processor and a power converter 117 of the control unit 110 of FIG. 1 so that the electric current value is at least approximately equal to the desired amount of electric current.

FIG. 6 is a functional block diagram of a computer system 600 that can be used in connection with the above-referenced cooling system of FIG. 1, and that can be utilized in implementing the process of FIG. 2 and the embodiments of the steps of FIGS. 3-5 in accordance with an exemplary embodiment of the present invention. In a preferred embodiment, the computer system 600 is part of or coupled to the control unit 110 of FIG. 1.

In the embodiment depicted in FIG. 6, the computer system 600 includes a processor 606, a memory 608, a computer bus 610, an interface 613, and a storage device 614. The processor 606 performs the computation and control functions of the of FIG. 1 or portions thereof, and may comprise any type of processor or multiple processors, single integrated circuits such as a microprocessor, or any suitable number of integrated circuit devices and/or circuit boards working in cooperation to accomplish the functions of a processing unit. During operation, the processor 606 executes one or more programs 612 preferably stored within the memory 608 and, as such, controls the general operation of the computer system 600.

The memory 608 stores a program or programs 612 that executes one or more embodiments of processes such as those described above in connection with FIGS. 2-5, and/or various steps thereof and/or other processes, such as those described elsewhere herein. The memory 608 can be any type of suitable memory. This would include the various types of dynamic random access memory (DRAM) such as SDRAM, the various types of static RAM (SRAM), and the various types of non-volatile memory (PROM, EPROM, and flash). It should be understood that the memory 608 may be a single type of memory component, or it may be composed of many different types of memory components. In addition, the memory 608 and the processor 606 may be distributed across several different computers that collectively comprise the computer system 600. For example, a portion of the memory 608 may reside on a computer within a particular apparatus or process, and another portion may reside on a remote computer.

The computer bus 610 serves to transmit programs, data, status and other information or signals between the various components of the computer system 600. The computer bus 610 can be any suitable physical or logical means of connecting computer systems and components. This includes, but is not limited to, direct hard-wired connections, fiber optics, infrared and wireless bus technologies.

The interface 613 allows communication to the computer system 600, for example from a system operator and/or another computer system, and can be implemented using any suitable method and apparatus. It can include one or more network interfaces to communicate within the sensing unit 108, other components of the control unit 110, the pump 106 of FIG. 1, and/or within or to other systems or components, one or more terminal interfaces to communicate with technicians, and one or more storage interfaces to connect to storage apparatuses such as the storage device 614.

The storage device 614 can be any suitable type of storage apparatus, including direct access storage devices such as hard disk drives, flash systems, floppy disk drives and optical disk drives. In one exemplary embodiment, the storage device 614 is a program product from which memory 608 can receive a program 612 that executes one or more embodiments of the process and/or steps thereof as described in greater detail further below. In one preferred embodiment, such a program product can be implemented as part of, inserted into, or otherwise coupled to the control unit 110 of FIG. 1. As shown in FIG. 6, the storage device 614 can comprise a disk drive device that uses disks 615 to store data. As one exemplary implementation, the computer system 600 may also utilize an Internet website, for example for providing or maintaining data or performing operations thereon.

It will be appreciated that while this exemplary embodiment is described in the context of a fully functioning computer system, those skilled in the art will recognize that the mechanisms of the present invention are capable of being distributed as a program product in a variety of forms, and that the present invention applies equally regardless of the particular type of computer-readable signal bearing media used to carry out the distribution. Examples of signal bearing media include: recordable media such as floppy disks, hard drives, memory cards and optical disks (e.g., disk 615), and transmission media such as digital and analog communication links. It will similarly be appreciated that the computer system 600 may also otherwise differ from the embodiment depicted in FIG. 6, for example in that the computer system 600 may be coupled to or may otherwise utilize one or more remote computer systems and/or other control systems.

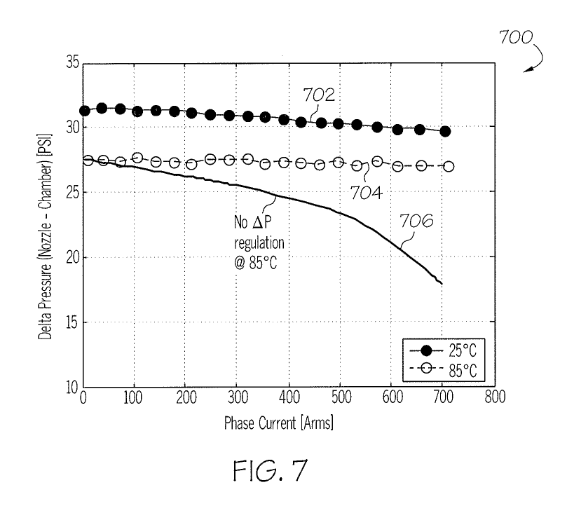

FIG. 7 is a plot 700 showing an effect of the cooling system 100 of FIG. 1 and the process 200 of FIG. 2 on a pressure difference with respect to a chamber of an inverter of a vehicle, in accordance with an exemplary embodiment of the present invention. Specifically, the plot 700 includes (i) a first graph 702 showing the pressure difference for an exemplary inverter at a temperature of twenty-five degrees Celsius, utilizing an exemplary embodiment of the cooling system 100 of FIG. 1 and the process 200 of FIG. 2 by using the pressure difference as the value of the variable; (ii) a second graph 704 showing the pressure difference for the same exemplary inverter at a temperature of eighty-five degrees Celsius, utilizing the same exemplary embodiment of the cooling system 100 of FIG. 1 and the process 200 of FIG. 2; and (iii) a third graph 706 showing the pressure difference for the same exemplary inverter at a temperature of eighty-five degrees Celsius with an unregulated flow of cooling fluid to the inverter. As shown in FIG. 7, the pressure difference (and thereby along with it, the rate of cooling flow) would ordinarily decrease as the electric current of high power inverter increases without pressure difference regulation.

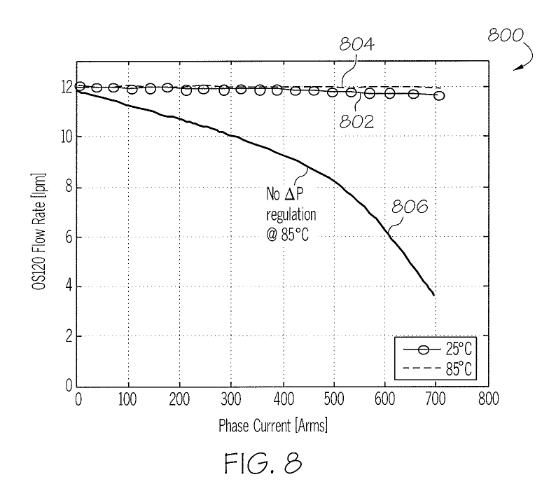

FIG. 8 is a plot 800 showing an effect of the cooling system 100 of FIG. 1 and the process 200 of FIG. 2 on a rate of flow of cooling fluid to an inverter of a vehicle, in accordance with an exemplary embodiment of the present invention. Specifically, the plot 800 includes (i) a first graph 802 showing the flow rate for an exemplary inverter at a temperature of twenty-five degrees Celsius, utilizing an exemplary embodiment of the cooling system 100 of FIG. 1 and the process 200 of FIG. 2 by using a pressure difference as the value of the variable; (ii) a second graph 804 showing the flow rate for the same exemplary inverter at a temperature of eighty-five degrees Celsius, utilizing the same exemplary embodiment of the cooling system 100 of FIG. 1 and the process 200 of FIG. 2; and (iii) a third graph 806 showing the flow rate for the same exemplary inverter at a temperature of eighty-five degrees Celsius with an unregulated flow of cooling fluid to the inverter. As shown in FIG. 8, the cooling system 100 of FIG. 1 and the process 200 of FIG. 2 allow for much more constant flow of cooling fluid to the inverter.

Accordingly, an improved system for cooling an inverter of a vehicle is provided that provides an approximately constant flow of cooling fluid to the inverter, and that potentially is more cost-effective and efficient and with improved performance as compared with traditional cooling systems. An improved program product is also provided for use in such an improved system. In addition, improved methods are provided for cooling an inverter of a vehicle is provided that provides an approximately constant flow of cooling fluid to the inverter, and that potentially is more cost-effective and efficient and with improved performance as compared with traditional cooling methods.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A method for cooling an inverter of a vehicle system, the method comprising the steps of:
providing a flow of cooling fluid to the inverter;
determining a value of a variable that is influenced at least in part by the flow of cooling fluid to the inverter; and
regulating the flow of cooling fluid to the inverter based at least in part on the value of the variable.

2. The method of claim 1, wherein the step of regulating the flow of cooling fluid to the inverter further comprises the step of maintain an at least approximately constant flow of cooling fluid to the inverter

3. The method of claim 2, wherein:
the step of providing a flow of cooling fluid to the inverter comprises the step of providing the flow of cooling fluid to the inverter at least in part via a nozzle;
the step of determining the value of the variable comprises the step of determining a pressure difference between a first pressure in the nozzle and a second pressure inside the inverter; and
the step of regulating the flow of cooling fluid to the inverter comprises the step of regulating the flow of cooling fluid to the inverter based at least in part on the pressure difference.

4. The method of claim 3, further comprising the step of:
comparing the pressure difference with a desired pressure difference, thereby generating a desired pressure comparison;
wherein the step of regulating the flow of cooling fluid to the inverter comprises the step of regulating the flow of cooling fluid to the inverter based at least in part on the desired pressure comparison.

5. The method of claim 4, wherein the flow of fluid is provided to the inverter by a pump that receives an electric current, and the method further comprises the steps of:
determining a measure of the electric current;
calculating a desired amount of electric current; and
comparing the measure of the electric current with the desired amount of electric current, thereby generating an electric current comparison;
wherein the step of regulating the flow of cooling fluid to the inverter comprises the step of regulating the flow of cooling fluid to the inverter based at least in part on the electric current comparison.

6. The method of claim 5, wherein the step of calculating the desired amount of electric current comprises the step of:
calculating the desired amount of electric current based at least in part on the desired pressure comparison.

7. The method of claim 2, wherein:
the step of determining the value of the variable comprises the step of determining the flow of cooling fluid to the inverter at a first point in time; and
the step of regulating the flow of cooling fluid to the inverter comprises the step of regulating the flow of cooling fluid to the inverter based at least in part on a flow comparison between the flow of cooling fluid at the first point in time and a desired flow of cooling fluid.

8. The method of claim 2, wherein:
the step of determining the value of the variable comprises the step of determining a phase current of the inverter; and
the step of regulating the flow of cooling fluid to the inverter comprises the step of regulating the flow of cooling fluid to the inverter based at least in part as function of the phase current of the inverter.

9. A program product for cooling an inverter of a vehicle system, the program product comprising:
(a) a program configured to at least facilitate:
providing a flow of cooling fluid to the inverter;
determining a value of a variable that is influenced at least in part by the flow of cooling fluid to the inverter; and
regulating the flow of cooling fluid to the inverter based at least in part on the value of the variable; and
(b) a computer-readable signal bearing media bearing the program.

10. The program product of claim 9, wherein the program is further configured to at least facilitate maintaining an at least approximately constant flow of cooling fluid to the inverter through the regulating of the flow of cooling fluid to the inverter.

11. The program product of claim 10, wherein:
the flow of cooling fluid is provided to the inverter at least in part via a nozzle; and
the value of the variable comprises a pressure difference between a first pressure in the nozzle and a second pressure inside the inverter.

12. The program product of claim 11, wherein the program is configured to at least facilitate:
comparing the pressure difference with a desired pressure difference, thereby generating a desired pressure comparison; and
regulating the flow of cooling fluid to the inverter based at least in part on the desired pressure comparison.

13. The program product of claim 12, wherein the flow of fluid is provided to the inverter by a pump that receives an electric current, and the program is configured to at least facilitate:
determining a measure of the electric current;
calculating a desired amount of electric current based at least in part on the desired pressure comparison;
comparing the measure of the electric current with the desired amount of electric current, thereby generating an electric current comparison; and
regulating the flow of cooling fluid to the inverter based at least in part on the electric current comparison.

14. The program product of claim 10, wherein the value of the variable comprises a flow comparison between the flow of cooling fluid to the inverter at a first point in time and a desired flow of cooling fluid to the inverter.

15. A cooling system for cooling an inverter of a vehicle system, the cooling system comprising:
a pump configured to at least facilitate providing a flow of cooling fluid to the inverter;
a sensing device configured to at least facilitate determining a value of a variable that is influenced at least in part by the flow of cooling fluid to the inverter; and
a control unit coupled to the sensing device and the pump and configured to at least facilitate regulating the flow of cooling fluid to the inverter based at least in part on the value of the variable.

16. The cooling system of claim 15, wherein the control unit is further configured to at least facilitate maintaining an at least approximately constant flow of cooling fluid to the inverter through the regulating of the flow of cooling fluid to the inverter.

17. The cooling system of claim 16, wherein:
the flow of cooling fluid is provided to the inverter at least in part via a nozzle;
the value of the variable comprises a pressure difference between a first pressure in the nozzle and a second pressure inside the inverter; and
the sensing device comprises:
a first sensor configured to at least facilitate measuring the first pressure; and
a second sensor configured to at least facilitate measuring the second pressure.

18. The cooling system of claim 16, wherein:
the value of the variable comprises a flow comparison between the flow of cooling fluid to the inverter at a first point in time and a desired flow of cooling fluid to the inverter; and
the sensing device comprises a flow meter configured to at least facilitate measuring the flow of cooling fluid to the inverter at the first point in time.

19. The cooling system of claim 16, wherein:
the pump comprises:
a turbine configured to at least facilitate providing the flow of cooling fluid to the inverter; and
a motor coupled to the turbine and configured to at least facilitate driving the turbine, based at least in part on an electric current; and
the control unit comprises:
a processor configured to at least facilitate generating an electric current command based at least in part on the value of the variable; and
a power converter coupled between the processor and the motor and configured to receive the electric current command from the processor and supply the electric current to the motor based at least in part on the electric current command.

20. The cooling system of claim 19, further comprising:
an additional sensing device configured to at least facilitate determining a measure of the electric current;
wherein the processor is configured to at least facilitate:
calculating a desired amount of electric current based at least in part on the value of the variable;
comparing the measure of the electric current with the desired amount of electric current, thereby generating an electric current comparison; and
generating the electric current command based at least in part on the electric current comparison.
